(19) United States
(12) Patent Application Publication
(10) Pub. No.: US 2026/0090372 A1
(43) Pub. Date: Mar. 26, 2026

(54) SEMICONDUCTOR PACKAGE

(71) Applicant: Samsung Electronics Co., Ltd., Suwon-si (KR)

(72) Inventors: Kyungdon Mun, Suwon-si (KR); Sehoon Jang, Suwon-si (KR); Jihwang Kim, Suwon-si (KR); Sangjin Baek, Suwon-si (KR)

(21) Appl. No.: 19/311,385

(22) Filed: Aug. 27, 2025

(30) Foreign Application Priority Data
Sep. 20, 2024 (KR) 10-2024-0127546

(51) Int. Cl. H01L 23/36; H01L 23/31; H01L 23/49; H01L 23/498; H01L 23/538

(52) U.S. Cl. CPC H10W 40/10; H10W 70/611; H10W 70/65; H10W 70/685; H10W 72/50; H10W 74/111; H10W 90/401; H10W 90/701

(57) ABSTRACT

A semiconductor package includes a first redistribution structure including a first redistribution insulating layer and a first redistribution conductive layer, a first semiconductor chip on the first redistribution structure, a molding member on the first redistribution structure and at least partially surrounding the first semiconductor chip, a second redistribution structure on the molding member and including a second redistribution insulating layer and a second redistribution conductive layer, a conductive post extending through the molding member to electrically connect the first redistribution conductive layer and the second redistribution conductive layer to each other, a second semiconductor chip on the second redistribution structure, a heat dissipation structure spaced apart from the second semiconductor chip in a horizontal direction and overlapping at least a portion of the first semiconductor chip in a vertical direction, and a thermal interface material between the second redistribution structure and the heat dissipation structure.

### CROSS-REFERENCE TO RELATED APPLICATION

This application is based on and claims priority under 35 U.S. C. § 119 to Korean Patent Application No. 10-2024-0127546, filed on Sep. 20, 2024 in the Korean Intellectual Property Office, the disclosure of which is incorporated by reference herein in its entirety.

### BACKGROUND

The inventive concept relates to a semiconductor package, and more particularly, to a semiconductor package including a plurality of semiconductor chips.

Recently, the demand for portable devices has rapidly increased in the electronic product market, and this had led to the miniaturization and weight reduction of electronic components installed in these products. In order to realize minimization and weight reduction of these electronic components, not only technology for reducing the size of each individual installed component but also semiconductor package technology for integrating a plurality of individual devices into a single package is required. In particular, as high-performance and high-capacity semiconductors are required, the number of semiconductor chips mounted on a semiconductor package is increasing. Due to the spatial constraints of semiconductor packages, technology for dissipating heat generated from semiconductor chips is required.

### SUMMARY

The inventive concept provides a semiconductor package with improved product reliability and improved heat dissipation characteristics by increasing a contact area between a redistribution structure and a thermal interface material to prevent interlayer separation between the redistribution structure and the thermal interface material.

However, technical objectives to be achieved by the inventive concept are not limited thereto, and other technical objectives will be apparent to one of ordinary skill in the art from the description of the inventive concept.

According to an aspect of the inventive concept, a semiconductor package includes a first redistribution structure including a first redistribution insulating layer and a first redistribution conductive layer, a first semiconductor chip on the first redistribution structure, a molding member on the first redistribution structure and at least partially surrounding the first semiconductor chip, a second redistribution structure on the molding member, and including a second redistribution insulating layer and a second redistribution conductive layer, a conductive post extending through the molding member to electrically connect the first redistribution conductive layer and the second redistribution conductive layer to each other, a second semiconductor chip on the second redistribution structure, a heat dissipation structure spaced apart from the second semiconductor chip in a horizontal direction and overlapping at least a portion of the first semiconductor chip in a vertical direction, and a thermal interface material between the second redistribution structure and the heat dissipation structure, wherein a top surface of the thermal interface material is a flat surface and a bottom surface of the thermal interface material is an uneven surface.

According to another aspect of the inventive concept, a semiconductor package includes a first redistribution structure including a first redistribution insulating layer and a first redistribution conductive layer, a first semiconductor chip on the first redistribution structure, a molding member on the first redistribution structure and at least partially surrounding the first semiconductor chip, a second redistribution structure on the molding member and including a second redistribution insulating layer and a second redistribution conductive layer, a plurality of conductive posts extending through the molding member to electrically connect the first redistribution conductive layer and the second redistribution conductive layer to each other, a second semiconductor chip on the second redistribution structure, a heat dissipation structure spaced apart from the second semiconductor chip in a horizontal direction and overlapping at least a major portion of the first semiconductor chip in a vertical direction, and a thermal interface material between the second redistribution structure and the heat dissipation structure, wherein the second redistribution conductive layer includes lower conductive patterns and an upper marking pad on the lower conductive patterns, wherein the upper marking pad includes a plurality of first marking pads on which a plurality of solder bumps disposed under the second semiconductor chip are seated and a plurality of second marking pads on which the thermal interface material is seated, wherein the plurality of second marking pads conformally contact the lower conductive patterns while filling a gap between the lower conductive patterns.

According to another aspect of the inventive concept, a semiconductor package includes a first redistribution structure including a first redistribution insulating layer and a first redistribution conductive layer, a first semiconductor chip on the first redistribution structure, a plurality of first connection bumps between the first semiconductor chip and the first redistribution structure, a molding member on the first redistribution structure and covering a top surface and a side surface of the first semiconductor chip, a second redistribution structure on the molding member, and including a second redistribution insulating layer and a second redistribution conductive layer, a plurality of conductive posts extending through the molding member to electrically connect the first redistribution conductive layer and the second redistribution conductive layer to each other, a second semiconductor chip on the second redistribution structure, a plurality of second connection bumps between the second semiconductor chip and the second redistribution structure, a heat dissipation structure spaced apart from the second semiconductor chip in a horizontal direction and overlapping at least a portion of the first semiconductor chip in a vertical direction, and a thermal interface material between the second redistribution structure and the heat dissipation structure, wherein the second redistribution conductive layer includes a plurality of first marking pads on which the plurality of second connection bumps are seated, a second marking pad on which the thermal interface material is seated, and a plurality of conductive patterns under the plurality of first marking pads and the second marking pad, wherein the second marking pad is integrally formed as a single body having an uneven structure, wherein the thermal interface material fills the uneven structure of the second marking pad.

### BRIEF DESCRIPTION OF THE DRAWINGS

Example embodiments will be more clearly understood from the following detailed description taken in conjunction with the accompanying drawings in which:

FIG. 1 is a cross-sectional view illustrating main elements of a semiconductor package, according to some embodiments;

FIG. 2 is an enlarged cross-sectional view illustrating a portion CX of FIG. 1, according to some embodiments;

FIG. 3 is an enlarged cross-sectional view illustrating a portion CX of FIG. 1, according to some other embodiments;

FIGS. 4 to 7 are plan views illustrating main elements of a semiconductor package, according to some embodiments;

FIGS. 8 to 16 are cross-sectional views illustrating, according to a process order, a method of manufacturing a semiconductor package, according to some embodiments; and

FIG. 17 is a diagram schematically illustrating a configuration of a semiconductor package, according to some embodiments.

### DETAILED DESCRIPTION

Hereinafter, example embodiments will be described in detail with reference to the accompanying drawings.

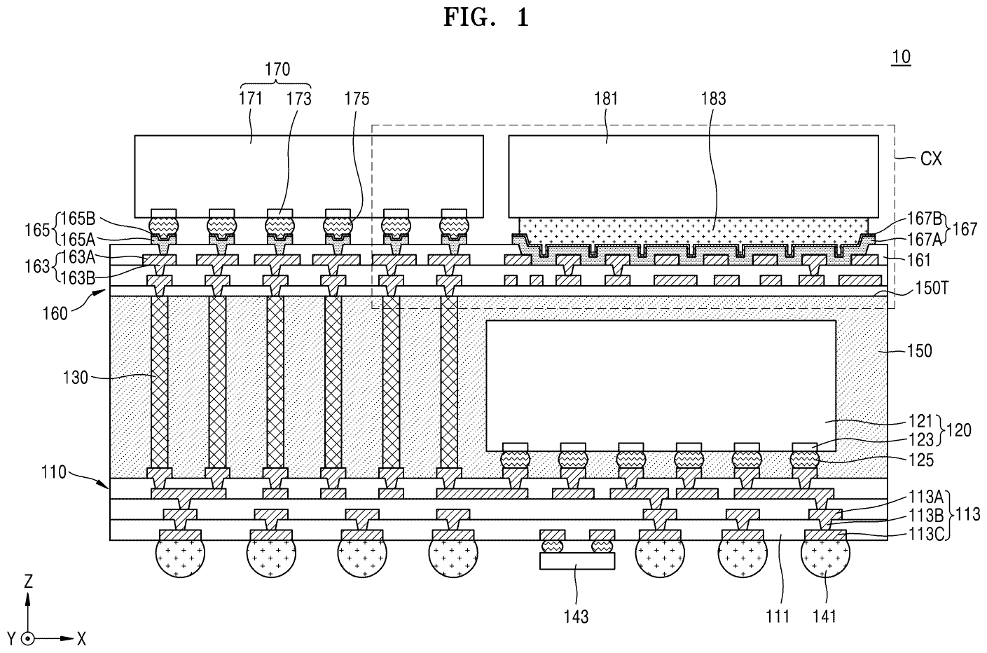

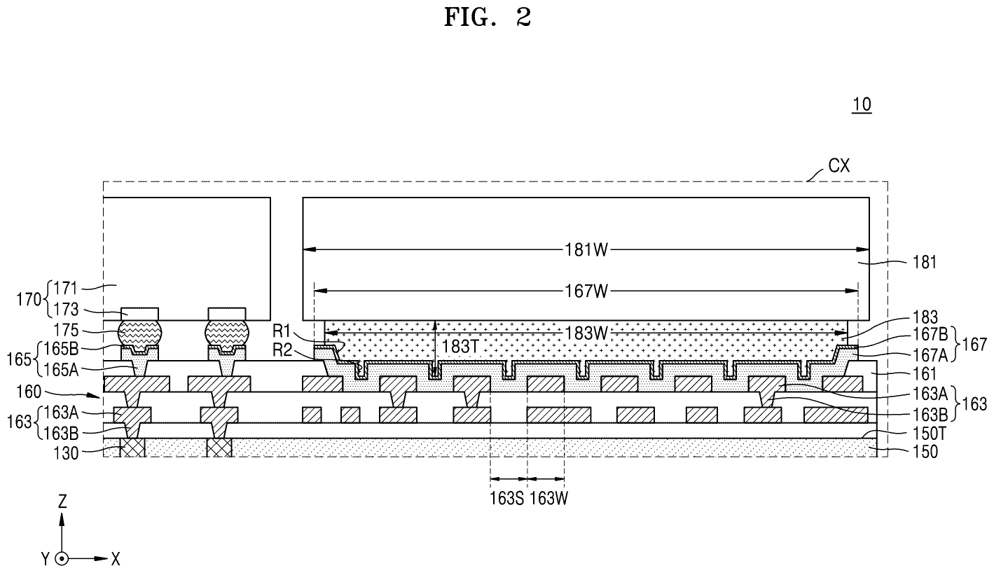

FIG. 1 is a cross-sectional view illustrating main elements of a semiconductor package, according to some embodiments. FIG. 2 is an enlarged cross-sectional view illustrating a portion CX of FIG. 1, according to some embodiments.

Referring to FIGS. 1 and 2 together, a semiconductor package 10 may include a first semiconductor chip 120 and a second semiconductor chip 170 which are vertically stacked, and may include a heat dissipation structure 181 and a thermal interface material 183.

In the semiconductor package 10 according to some embodiments, a first redistribution structure 110 may be a package substrate on which the first semiconductor chip 120 is mounted. The first redistribution structure 110 may have a substantially flat plate shape or panel shape. The first redistribution structure 110 may include a top surface and a bottom surface facing or opposite each other, and the top surface and the bottom surface of the first redistribution structure 110 may be substantially flat or planar surfaces.

A footprint or planar area of the first redistribution structure 110 may be greater than a footprint or planar area of the first semiconductor chip 120. A footprint or planar area of the first redistribution structure 110 may be substantially the same as a footprint or planar area of the semiconductor package 10.

Hereinafter, a horizontal direction (e.g., an X direction and/or a Y direction) may be defined as a direction parallel to the top surface or the bottom surface of the first redistribution structure 110, a vertical direction (e.g., a Z direction) may be defined as a direction perpendicular to the top surface or the bottom surface of the first redistribution structure 110, and a horizontal width may be defined as a length in the horizontal direction (X direction and/or Y direction).

The first redistribution structure 110 may include a first redistribution insulating layer 111 and a first redistribution conductive layer 113. The first redistribution insulating layer 111 may include a plurality of insulating layers stacked on each other in the vertical direction (Z direction). The first redistribution insulating layer 111 may be formed of, for example, an insulating polymer, epoxy, or a combination thereof. In some embodiments, the first redistribution insulating layer 111 may be formed of a photo imageable dielectric (PID) or photosensitive polyimide (PSPI).

The first redistribution conductive layer 113 may include a first conductive pattern 113A, a first via pattern 113B, and an external connection pad 113C. The first conductive pattern 113A may extend in the horizontal direction (X direction and/or Y direction), and may have a multi-layer structure located at different vertical levels. The first conductive pattern 113A may be disposed on any one of a top surface and a bottom surface of each insulating layer of the first redistribution insulating layer 111. For example, the first conductive pattern 113A may include a line pattern extending in a line shape along any one of a top surface and a bottom surface of any one insulating layer of the first redistribution insulating layer 111. The first conductive pattern 113A provided on an uppermost insulating layer of the first redistribution insulating layer 111 may include a pad to which a first connection bump 125 is attached and a pad to which a plurality of conductive posts 130 are attached.

The first via pattern 113B may extend in the vertical direction (Z direction) by passing through at least one insulating layer of the first redistribution insulating layer 111. The first via pattern 113B may electrically connect the first conductive patterns 113A located at different vertical levels or may electrically connect the first conductive pattern 113A to the external connection pad 113C.

The external connection pad 113C may be disposed on the bottom surface of the first redistribution structure 110 and may contact an external connection terminal 141. The external connection terminal 141 may be electrically connected to the first semiconductor chip 120 and/or the plurality of conductive posts 130 through the first redistribution conductive layer 113.

The first redistribution conductive layer 113 may include, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

At least a part of the first conductive pattern 113A may be integrally formed to form one body with the first via pattern 113B. For example, the first conductive pattern 113A and the first via pattern 113B connected to each other may be formed together through an electroplating process.

In some embodiments, the first via pattern 113B may have a tapered shape whose horizontal width decreases downwardly. That is, a horizontal width of the first via pattern 113B may decrease closer to a top surface of the external connection pad 113C.

Although not shown, a seed metal layer may be disposed on a surface of the first conductive pattern 113A and a surface of the first via pattern 113B. For example, the seed metal layer may be disposed between a bottom surface of the first conductive pattern 113A and the first redistribution insulating layer 111, and may be disposed between each of a side wall (or side surface) and a bottom surface of the first via pattern 113B and the first redistribution insulating layer 111. Also, the seed metal layer may be disposed between the first via pattern 113B and the external connection pad 113C. Also, the seed metal layer may be disposed between the external connection pad 113C and the external connection terminal 141. The seed metal layer may include any one of, for example, copper (Cu), titanium (Ti), titanium tungsten (TiW), titanium nitride (TiN), tantalum (Ta), tantalum nitride (TaN), chromium (Cr), and aluminum (Al). The seed metal layer may be formed through a physical vapor deposition process such as sputtering.

In some embodiments, in a cross-sectional view, the external connection pad 113C may have a rectangular shape. In some embodiments, the bottom surface of the external connection pad 113C may be located substantially on the same plane as a bottom surface of the first redistribution insulating layer 111. That is, the bottom surface of the external connection pad 113C and the bottom surface of the first redistribution insulating layer 111 may be coplanar or substantially coplanar. In some embodiments, the external connection pad 113C may include a plurality of metal layers stacked in the vertical direction (Z direction).

The external connection terminal 141 may be attached or connected to the external connection pad 113C of the first redistribution structure 110. The external connection terminal 141 may be configured to electrically and physically connect the first redistribution structure 110 to an external device. The external connection terminal 141 may be formed of, for example, a solder ball or a solder bump.

At least one passive component 143 may be attached or connected below the first redistribution structure 110. The passive component 143 may be attached or connected below the first redistribution structure 110 through a solder bump.

The first semiconductor chip 120 may be mounted on one side (e.g., a right side in FIG. 1) of the first redistribution structure 110. The first semiconductor chip 120 may be electrically and physically connected to the first redistribution conductive layer 113 of the first redistribution structure 110 through the first connection bump 125. The first connection bump 125 may be disposed between the first semiconductor chip 120 and the first conductive pattern 113A disposed on the uppermost insulating layer of the first redistribution insulating layer 111. The first connection bump 125 may include a solder bump, for example.

In some embodiments, the first semiconductor chip 120 may include a first semiconductor substrate 121, and a first connection pad 123 that is disposed under the first semiconductor substrate 121 and to which the first connection bump 125 is attached or connected.

The first semiconductor substrate 121 may be formed from a semiconductor wafer. The first semiconductor substrate 121 may include, for example, silicon (Si). Alternatively, the first semiconductor substrate 121 may include a semiconductor element such as germanium (Ge), or a compound semiconductor such as silicon carbide (SiC), gallium arsenide (GaAs), indium arsenide (InAs), or indium phosphide (InP).

The first semiconductor chip 120 may include a semiconductor device layer provided on an active surface (e.g., a bottom surface) of the first semiconductor substrate 121. The semiconductor device layer of the first semiconductor chip 120 may include an individual device (not shown). The individual device may include, for example, a logic device, a memory device, an active device, or a passive device.

In some embodiments, the first semiconductor chip 120 may include a single semiconductor chip as shown in FIG. 1, or may include two or more semiconductor chips stacked in the vertical direction (Z direction).

A molding member 150 may be formed on the first redistribution structure 110. The molding member 150 may at least partially cover the first semiconductor chip 120 and the first redistribution structure 110. The molding member 150 may surround a side wall and a top surface of the first semiconductor chip 120. Also, the molding member 150 may surround the first connection bump 125 (or a side wall or side surface thereof) while being in or filling a gap between the first semiconductor chip 120 and the first redistribution structure 110. The molding member 150 may include, for example, an epoxy-based molding resin or a polyimide-based molding resin. In some embodiments, the molding member 150 may include an epoxy molding compound.

The plurality of conductive posts 130 may be disposed on the other side (e.g., a left side in FIG. 1) of the first redistribution structure 110. The plurality of conductive posts 130 may electrically connect the first redistribution conductive layer 113 of the first redistribution structure 110 to a second redistribution conductive layer 163 of a second redistribution structure 160 described below. The plurality of conductive posts 130 may pass through the molding member 150 in the vertical direction (Z direction). A lower portion or lower end of each of the plurality of conductive posts 130 may contact the first conductive pattern 113A disposed on the uppermost insulating layer of the first redistribution insulating layer 111, and an upper portion or upper end of each of the plurality of conductive posts 130 may contact the second redistribution conductive layer 163. In some embodiments, a top surface of each of the plurality of conductive posts 130 may be located on the same plane as a top surface 150T of the molding member 150. That is, the top surface of each of the plurality of conductive posts 130 and the top surface 150T of the molding member 150 may be coplanar or substantially coplanar. The plurality of conductive posts 130 may include, for example, copper (Cu).

The second redistribution structure 160 may be disposed on the molding member 150 and the plurality of conductive posts 130. In some embodiments, a footprint or planar area of the second redistribution structure 160 may be the same as a footprint or planar area of the first redistribution structure 110. In some embodiments, a side wall or side surface of the second redistribution structure 160 may be aligned with a corresponding side wall or side surface of the molding member 150 and a corresponding side wall or side surface of the first redistribution structure 110 in the vertical direction (Z direction). That is, a side wall of the second redistribution structure 160, a corresponding side wall of the molding member 150, and a corresponding side wall of the first redistribution structure 110 may be coplanar or substantially coplanar.

The second redistribution structure 160 may include a second redistribution insulating layer 161 and the second redistribution conductive layer 163. The second redistribution insulating layer 161 may include a plurality of insulating layers stacked on each other in the vertical direction (Z direction). The second redistribution insulating layer 161 may be formed of an insulating polymer, epoxy, or a combination thereof. The second redistribution insulating layer 161 may be formed of, for example, PID or photosensitive polyimide.

The second redistribution conductive layer 163 may include a second conductive pattern 163A and a second via pattern 163B. The second conductive pattern 163A may be disposed on any one of a top surface and a bottom surface of any one insulating layer of the second redistribution insulating layer 161. The second conductive pattern 163A may have a multi-layer structure located at different vertical levels. For example, the second conductive pattern 163A may include a line pattern extending in a line shape along a top surface or a bottom surface of any one insulating layer of the second redistribution insulating layer 161.

In the semiconductor package 10 according to some embodiments, a plurality of first marking pads 165 on which a plurality of second connection bumps 175 described below are seated and a second marking pad 167 on which the thermal interface material 183 described below is seated may be disposed on an uppermost insulating layer of the second redistribution insulating layer 161. The plurality of first marking pads 165 may be electrically separated or electrically isolated from each other in the horizontal direction (X direction and/or Y direction) by the second redistribution insulating layer 161, and the second marking pad 167 may be integrally formed as one body connected or extending in the horizontal direction (X direction and/or Y direction).

In some embodiments, each of the plurality of first marking pads 165 may include a first pad layer 165A and a first coating layer 165B conformally covering the first pad layer 165A disposed under the first coating layer 165B. The plurality of first marking pads 165 may have a multi-layer structure including a plurality of metals selected from among, for example, copper (Cu), nickel (Ni), and gold (Au). Likewise, the second marking pad 167 may include a second pad layer 167A and a second coating layer 167B conformally covering the second pad layer 167A disposed under the second coating layer 167B. The second marking pad 167 may have a multi-layer structure including a plurality of metals selected from among, for example, copper (Cu), nickel (Ni), and gold (Au).

That is, the second redistribution conductive layer 163 may include the plurality of first marking pads 165 and one second marking pad 167 disposed on the second conductive pattern 163A. Each of the plurality of first marking pads 165 may contact a top surface of the second conductive pattern 163A. Unlike this, one second marking pad 167 may conformally formed while contacting a top surface and a side wall of each of the second conductive patterns 163A to fill a gap between the second conductive patterns 163A. That is, one second marking pad 167 may include a two-stage uneven structure including a first recess portion R1 and a plurality of second recess portions R2 disposed inside the first recess portion R1.

According to such a structural difference, a vertical level of an uppermost surface of the plurality of first marking pads 165 may be substantially the same as a vertical level of an uppermost surface of the second marking pad 167, and a vertical level of a lowermost surface of the plurality of first marking pads 165 may be higher than a vertical level of a lowermost surface of the second marking pad 167.

In some embodiments, a horizontal width 163W of each second conductive pattern 163A located on an uppermost layer from among the second conductive patterns 163A may be about 10 micrometers (μm) to about 30 μm, and a separation distance or horizontal spacing 163S between adjacent second conductive patterns 163A may be about 10 μm to about 30 μm. The separation distance 163S between the second conductive patterns 163A may be equal to or greater than the horizontal width 163W of each second conductive pattern 163A. This is to efficiently form the two-stage uneven structure of the second marking pad 167.

The second conductive pattern 163A located on a lowermost layer from among the second conductive patterns 163A may include or be connected to the second via pattern 163B contacting the plurality of conductive posts 130. The second via pattern 163B may extend in the vertical direction (Z direction) by passing through at least one insulating layer of the second redistribution insulating layer 161. The second via pattern 163B may electrically connect the second conductive patterns 163A located at different vertical levels or may electrically connect the second conductive pattern 163A to the plurality of conductive posts 130. The second redistribution conductive layer 163 may include, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof.

At least a part of the second conductive pattern 163A may be integrally formed with the second via pattern 163B. For example, the second conductive pattern 163A and the second via pattern 163B connected to each other may be formed together through an electroplating process.

Although not shown, a seed metal layer may be disposed on a surface of the second conductive pattern 163A and a surface of the second via pattern 163B. The seed metal layer may be substantially the same as described above, and thus, a detailed description thereof will be omitted in the interest of brevity.

In some embodiments, the second via pattern 163B may have a tapered shape whose horizontal width decreases downwardly. That is, a horizontal width of the second via pattern 163B may gradually decrease closer to the top surface 150T of the molding member 150 or the top surfaces of the plurality of conductive posts 130.

The second semiconductor chip 170 may be disposed on the second redistribution structure 160. For example, the second semiconductor chip 170 may include a second semiconductor substrate 171 and a second connection pad 173. The second connection pad 173 of the second semiconductor chip 170 may be electrically and physically connected to the second redistribution conductive layer 163 of the second redistribution structure 160 through the second connection bump 175.

The first semiconductor chip 120 and the second semiconductor chip 170 may include different types of chips. Each of the first semiconductor chip 120 and the second semiconductor chip 170 may include, for example, a memory chip, a logic chip, a system-on-chip (SOC), a power management integrated circuit (PMIC) chip, or a radio frequency integrated circuit (RFIC) chip. In some embodiments, the first semiconductor chip 120 may be a logic chip, and the second semiconductor chip 170 may be a memory chip.

The memory chip may include a dynamic random-access memory (DRAM) chip, a static random-access memory (SRAM) chip, a magnetoresistive random-access memory (MRAM) chip, a NAND flash memory chip, or a high bandwidth memory (HBM) chip. The logic chip may include an application processor (AP), a microprocessor, a central processing unit (CPU), a controller, or an application specific integrated circuit (ASIC).

The heat dissipation structure 181 may be disposed on the second redistribution structure 160 to overlap most or at least a major portion of the first semiconductor chip 120 in the vertical direction (Z direction). The heat dissipation structure 181 may be thermally coupled to the first semiconductor chip 120. The heat dissipation structure 181 may include a heat sink, a heat pipe, or a heat slug. Heat generated from the first semiconductor chip 120 may be discharged to the outside through the heat dissipation structure 181. The heat dissipation structure 181 may include a thermally conductive material having a high thermal conductivity. A thermal conductivity of a material of the heat dissipation structure 181 may be greater than a thermal conductivity of silicon (Si). That is, the thermal resistance of a material of the heat dissipation structure 181 may be less than the thermal resistance of silicon. For example, the heat dissipation structure 181 may include a metal such as copper (Cu) or aluminum (Al), or a carbon-containing material such as graphene, graphite, or carbon nanotubes.

The heat dissipation structure 181 may be attached or connected to the second redistribution structure 160 through the thermal interface material 183. The thermal interface material 183 may include a thermally conductive and electrically insulating material. The thermal interface material 183 may include, for example, a polymer including metal powder, thermal grease, or a combination thereof.

The thermal interface material 183 may have a top surface contacting the heat dissipation structure 181 and a bottom surface contacting the second marking pad 167. The top surface of the thermal interface material 183 may be a flat or planar surface, and the bottom surface may be an uneven surface. That is, the uneven surface of the thermal interface material 183 may have a shape engaged with or mating with the two-stage uneven structure or surface of the second marking pad 167.

In some embodiments, a thickness 183T (e.g., a maximum thickness) of the thermal interface material 183 in the vertical direction (Z direction) may be about 45 μm to about 55 μm. When the thickness 183T is less than 45 μm, it may be difficult for the thermal interface material 183 to be engaged with the two-stage uneven structure of the second marking pad 167, and when the thickness 183T is greater than 55 μm, heat transfer characteristics may be degraded.

In the semiconductor package 10 according to some embodiments, the thermal interface material 183 may be formed to fill the two-stage uneven structure of the second marking pad 167 and expose both side walls (e.g., opposite side walls or side surfaces) of the second marking pad 167. In other words, the thermal interface material 183 may contact the second redistribution conductive layer 163, but may not contact the second redistribution insulating layer 161. That is, a horizontal width 183W of the thermal interface material 183 may be less than a horizontal width 167W of the second marking pad 167. Also, the horizontal width 183W of the thermal interface material 183 may be less than a horizontal width 181W of the heat dissipation structure 181.

In some embodiments, a second planar area of the thermal interface material 183 may be less than a first planar area of the heat dissipation structure 181. In detail, the second planar area may be about 70% to about 90% of the first planar area. When the second planar area is less than 70% of the first planar area, heat transfer characteristics may be degraded, and when the second planar area is greater than 90% of the first planar area, the thermal interface material 183 may overflow laterally during an attachment process to affect the second semiconductor chip 170.

A signal (e.g., a data signal, a control signal, a power supply signal, and/or a ground signal) provided from an external device may be provided to the first semiconductor chip 120 through a signal transmission path including the external connection terminal 141 and the first redistribution conductive layer 113. A signal provided from the external device may be provided to the second semiconductor chip 170 through a signal transmission path including the external connection terminal 141, the first redistribution conductive layer 113, the plurality of conductive posts 130, and the second redistribution conductive layer 163. An electrical signal between the first semiconductor chip 120 and the second semiconductor chip 170 may be transmitted through the first redistribution conductive layer 113, the plurality of conductive posts 130, and the second redistribution conductive layer 163.

In this signal transmission and processing process, a heat generation amount of the first semiconductor chip 120 may be greater than a heat generation amount of the second semiconductor chip 170. That is, because the first semiconductor chip 120 having a larger heat generation amount is thermally coupled to the heat dissipation structure 181 through the thermal interface material 183, heat dissipation characteristics of the first semiconductor chip 120 may be improved, and the performance of the semiconductor package 10 may be prevented from being degraded due to heat generation of the first semiconductor chip 120.

However, in a general semiconductor package, the thermal interface material 183 has a substantially flat bottom surface contacting the second redistribution conductive layer 163 and the second redistribution insulating layer 161. In this case, because thermal expansion coefficients of materials of the second redistribution conductive layer 163 and the second redistribution insulating layer 161 contacting the thermal interface material 183 are different from each other and a contact area between the thermal interface material 183 and the second redistribution structure 160 is relatively small, undesirable interlayer separation may occur at a bonding interface between the thermal interface material 183 and the second redistribution structure 160, which may degrade heat dissipation characteristics of the semiconductor package.

To solve this problem, the semiconductor package 10 according to the inventive concept may form one second marking pad 167 having the two-stage uneven structure on the second redistribution structure 160 to prevent interlayer separation between the thermal interface material 183 and the second redistribution structure 160. Accordingly, a contact area between the second redistribution structure 160 and the thermal interface material 183 may increase, and thus, the effect of increasing product reliability and improving heat dissipation characteristics may be expected.

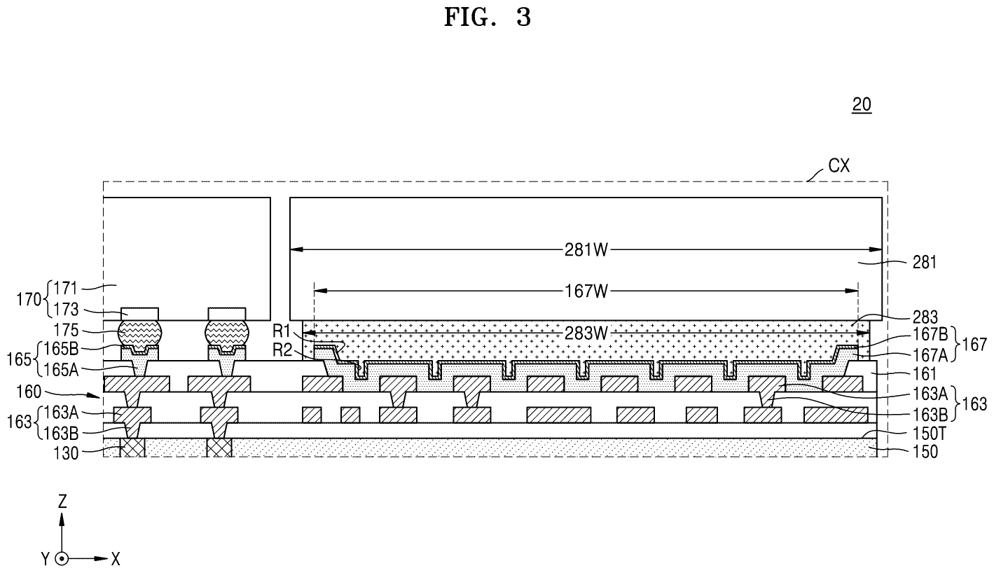

FIG. 3 is an enlarged cross-sectional view illustrating a portion CX of FIG. 1, according to some other embodiments.

Most of elements constituting a semiconductor material 20 described below and materials of the elements are substantially the same as or similar to those described with reference to FIGS. 1 and 2. Accordingly, for convenience of explanation and in the interest of brevity, a difference from the semiconductor package 10 described above will be mainly described.

Also, for convenience of explanation and in the interest of brevity, only elements corresponding to a portion CX from among the elements of the semiconductor package 20 are illustrated.

Referring to FIG. 3, the semiconductor package 20 may include a heat dissipation structure 281 and a thermal interface material 283.

In the semiconductor package 20 according to some embodiments, the heat dissipation structure 281 may be disposed to overlap most or at least a major portion of the first semiconductor chip 120 in the vertical direction (Z direction), and may be attached or connected to the thermal interface material 283.

In the semiconductor package 20 according to some embodiments, the thermal interface material 283 may have a top surface contacting the heat dissipation structure 281 and a bottom surface contacting the second marking pad 167. The top surface of the thermal interface material 283 may be a flat or planar surface, and the bottom surface may be an uneven surface. That is, the uneven surface of the thermal interface material 283 may have a shape engaged with or mating with the two-stage uneven structure or surface of the second marking pad 167.

In the semiconductor package 20 according to some embodiments, the thermal interface material 283 may be formed to fill the two-stage uneven structure of the second marking pad 167 and surround both side walls (e.g., opposite side walls or side surfaces) of the second marking pad 167. In other words, the thermal interface material 283 may contact the second redistribution conductive layer 163 and the second redistribution insulating layer 161. That is, a horizontal width 283W of the thermal interface material 283 may be greater than the horizontal width 167W of the second marking pad 167. Also, the horizontal width 283W of the thermal interface material 283 may be less than a horizontal width 281W of the heat dissipation structure 281.

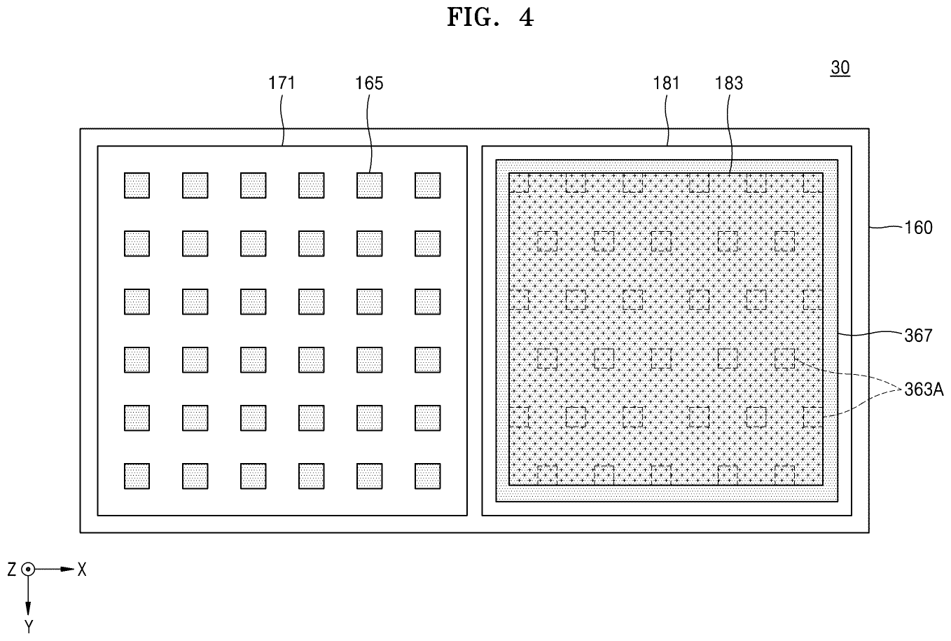

FIGS. 4 to 7 are plan views illustrating main elements of a semiconductor package, according to some embodiments.

Hereinafter, most of elements constituting semiconductor packages 30, 40, 50, and 60 described below and materials of the elements are substantially the same as or similar to those described with reference to FIGS. 1 and 2. Accordingly, for convenience of explanation and in the interest of brevity, a difference from the semiconductor package 10 described above will be mainly described.

Also, for convenience of explanation and in the interest of brevity, the second semiconductor chip 170, the heat dissipation structure 181, and the thermal interface material 183 included in each of the semiconductor packages 30, 40, 50, and 60 are illustrated so that elements thereunder are visible, and schematic positions of second conductive patterns 363A, 463A, 563A, and 663A are marked by dashed lines.

Referring to FIG. 4, the semiconductor package 30 may include the second conductive patterns 363A and a second marking pad 367.

In the semiconductor package 30 according to some embodiments, the second marking pad 367 may have one quadrangular shape. The second marking pad 367 may have a multi-layer structure including a plurality of metals selected from among copper (Cu), nickel (Ni), and gold (Au).

The semiconductor package 30 according to some embodiments may include the plurality of first marking pads 165 and one second marking pad 367 located on the second conductive patterns 363A arranged at constant intervals. The plurality of first marking pads 165 may contact top surfaces of the second conductive patterns 363A. Unlike this, one second marking pad 367 may be conformally formed while contacting a top surface and a side wall or side surface of each of the second conductive patterns 363A to fill a gap between the second conductive patterns 363A. One second marking pad 367 may have a two-stage uneven structure or surface.

In the semiconductor package 30 according to some embodiments, the thermal interface material 183 may be formed to fill the two-stage uneven structure of one second marking pad 367 having a quadrangular shape.

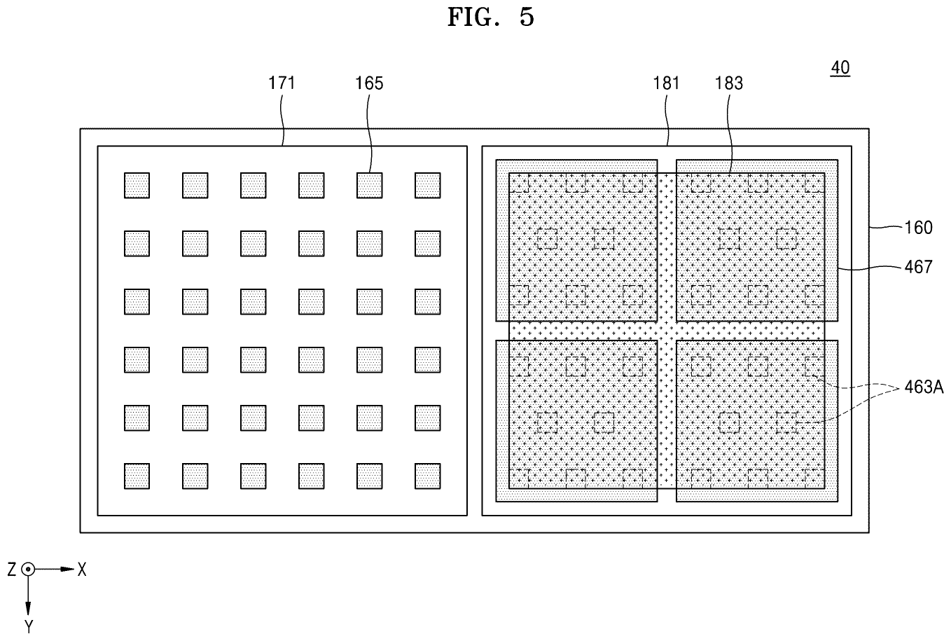

Referring to FIG. 5, the semiconductor package 40 may include the second conductive patterns 463A and a plurality of second marking pads 467.

In the semiconductor package 40 according to some embodiments, each of the plurality of second marking pads 467 may have a quadrangular shape. Also, the plurality of second marking pads 467 may be arranged at constant intervals in the horizontal direction (X direction and/or Y direction). Each of the plurality of second marking pads 467 may have a multi-layer structure including a plurality of metals selected from among, for example, copper (Cu), nickel (Ni), and gold (Au).

The semiconductor package 40 according to some embodiments may include the plurality of first marking pads 165 and the plurality of second marking pads 467 located on the second conductive patterns 463A arranged at constant intervals. The plurality of first marking pads 165 may contact top surfaces of the second conductive patterns 463A. Unlike this, the plurality of second marking pads 467 may be conformally formed while contacting a top surface and a side wall or side surface of each of the second conductive patterns 463A to fill a gap between the second conductive patterns 463A. That is, each of the plurality of second marking pads 467 may have a two-stage uneven structure or surface.

In the semiconductor package 40 according to some embodiments, the thermal interface material 183 may be formed to fill the two-stage uneven structure of each of the plurality of second marking pads 467 arranged at constant intervals.

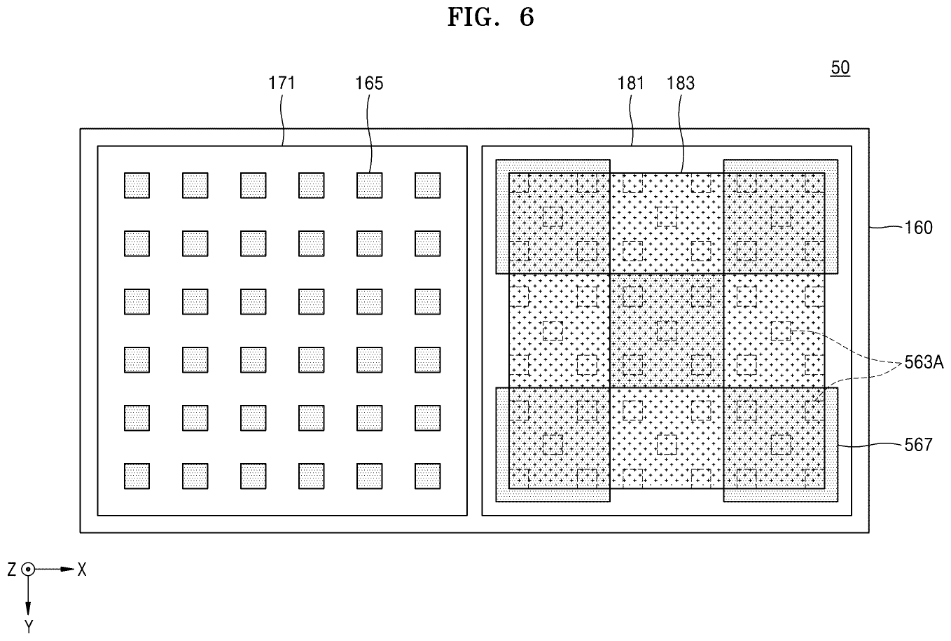

Referring to FIG. 6, the semiconductor package 50 may include the second conductive patterns 563A and a plurality of second marking pads 567.

In the semiconductor package 50 according to some embodiments, each of the plurality of second marking pads 567 may have a quadrangular shape. Also, the plurality of second marking pads 567 may be arranged in a zigzag shape or a staggered grid shape in the horizontal direction (X direction and/or Y direction). Each of the plurality of second marking pads 567 may have a multi-layer structure including a plurality of metals selected from among copper (Cu), nickel (Ni), and gold (Au),

The semiconductor package 50 according to some embodiments may include the plurality of first marking pads 165 and the plurality of second marking pads 567 located on the second conductive patterns 563A arranged at constant intervals. The plurality of first marking pads 165 may contact top surfaces of the second conductive patterns 563A. Unlike this, the plurality of second marking pads 567 may be conformally formed while contacting a top surface and a side wall or side surface of each of the second conductive patterns 563A to fill a gap between the second conductive patterns 563A. That is, each of the plurality of second marking pads 567 may have a two-stage uneven structure.

In the semiconductor package 50 according to some embodiments, the thermal interface material 183 may be formed to fill the two-stage uneven structure of each of the plurality of second marking pads 567 arranged in a zigzag shape or a staggered grid shape.

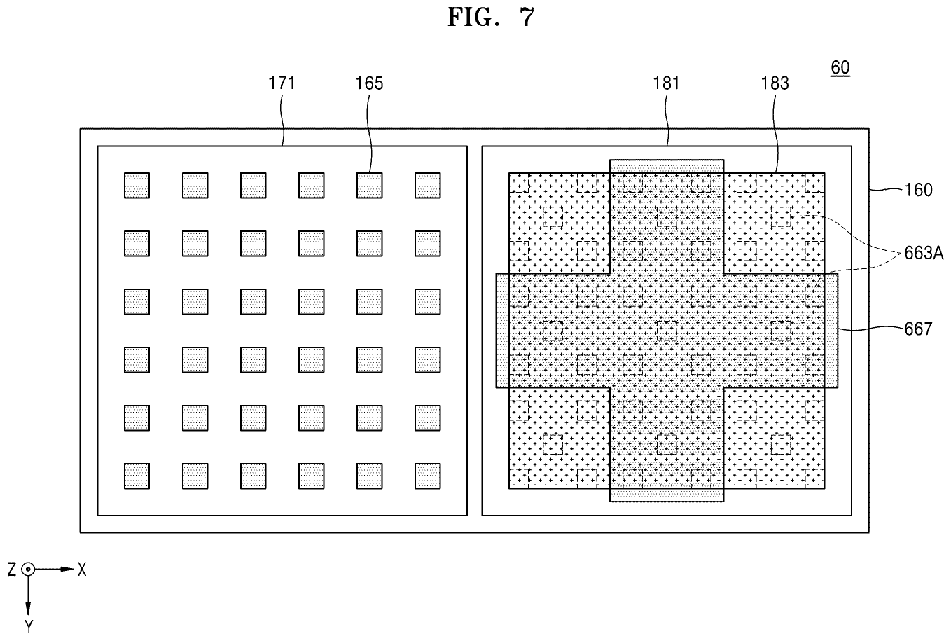

Referring to FIG. 7, the semiconductor package 60 may include the second conductive patterns 663A and a second marking pad 667.

In the semiconductor package 60 according to some embodiments, the second marking pad 667 may have one cross shape. For example, the second marking pad 667 may include a first portion that is elongated in the X direction and a second portion that intersects the first portion and that is elongated in the Y direction. The second marking pad 667 may have a multi-layer structure including a plurality of metals selected from among copper (Cu), nickel (Ni), and gold (Au).

The semiconductor package 60 according to some embodiments may include the plurality of first marking pads 165 and one second marking pad 667 located on the second conductive patterns 663A arranged at constant intervals. The plurality of first marking pads 165 may contact top surfaces of the second conductive patterns 663A. Unlike this, one second marking pad 667 may be conformally formed while contacting a top surface and a side wall of each of the second conductive patterns 663A to fill a gap between the second conductive patterns 663A. That is, one second marking pad 667 may have a two-stage uneven structure.

In the semiconductor package 60 according to some embodiments, the thermal interface material 183 may be formed to fill the two-stage uneven structure of one second marking pad 667 having a cross shape.

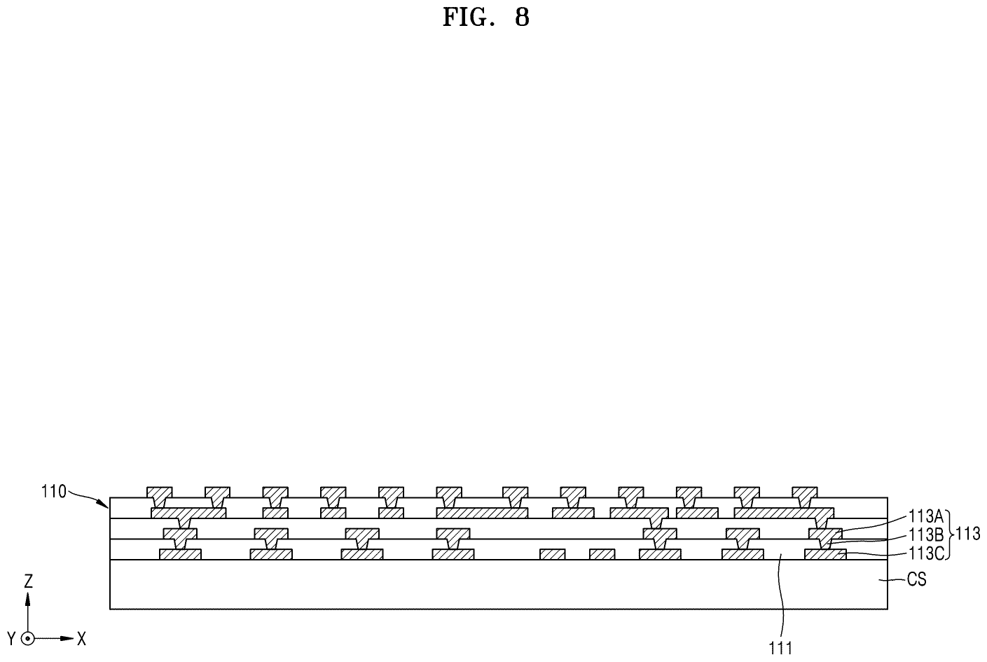

FIGS. 8 to 16 are cross-sectional views illustrating, according to a process order, a method of manufacturing a semiconductor package, according to some embodiments.

Referring to FIG. 8, the first redistribution structure 110 may be formed on a carrier substrate CS.

The first redistribution structure 110 may include the first redistribution insulating layer 111 and the first redistribution conductive layer 113, insulated by the first redistribution insulating layer 111, which are sequentially stacked on the carrier substrate CS. The first redistribution conductive layer 113 may include the first conductive pattern 113A extending along a top surface of any one insulating layer of the first redistribution insulating layer 111, the first via pattern 113B extending by passing through any one insulating layer of the first redistribution insulating layer 111, and the external connection pad 113C extending along a top surface of the carrier substrate CS.

To form the first redistribution structure 110, the external connection pad 113C may be first formed on the carrier substrate CS. The external connection pad 113C may be formed through a plating process. For example, after a seed metal layer (not shown) is formed on the carrier substrate CS, the external connection pad 113C may be formed by performing a plating process using the seed metal layer.

After the external connection pad 113C is formed, the first redistribution insulating layer 111 covering the external connection pad 113C and having a via hole may be formed, and the first via pattern 113B filling the via hole of the first redistribution insulating layer 111 and the first conductive pattern 113A extending along a top surface of the first redistribution insulating layer 111 may be formed. The first redistribution structure 110 having a multi-layer wiring structure may be formed by repeatedly performing several times a process of forming the first redistribution insulating layer 111 and the first conductive pattern 113A.

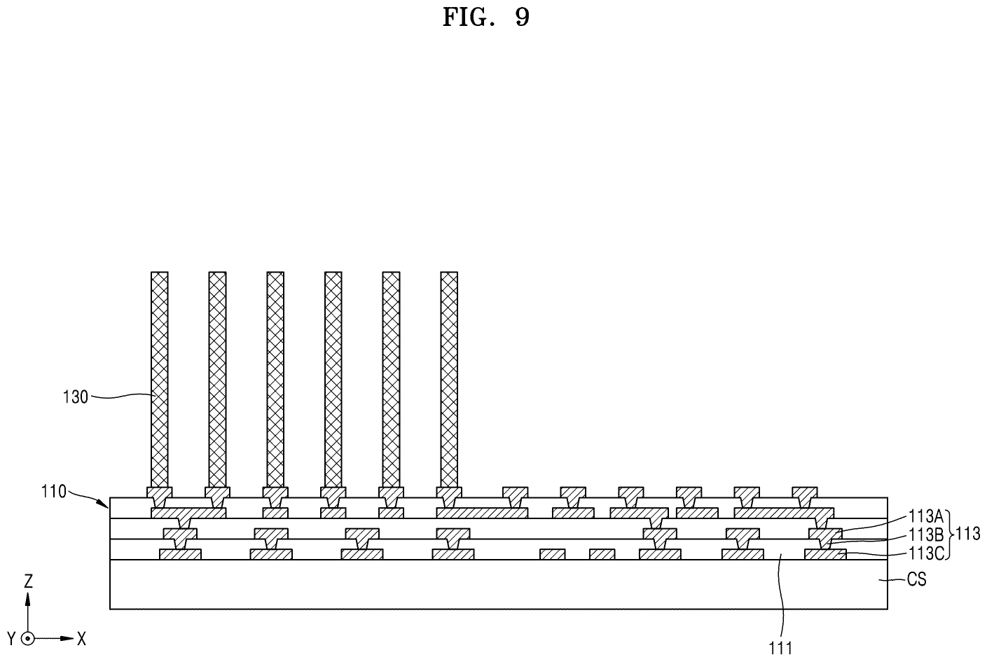

Referring to FIG. 9, the plurality of conductive posts 130 may be formed on the first redistribution structure 110.

The plurality of conductive posts 130 may be formed by forming a mask pattern (not shown) having a plurality of holes and performing a plating process to fill the plurality of holes. After the plurality of conductive posts 130 are formed, the mask pattern may be removed.

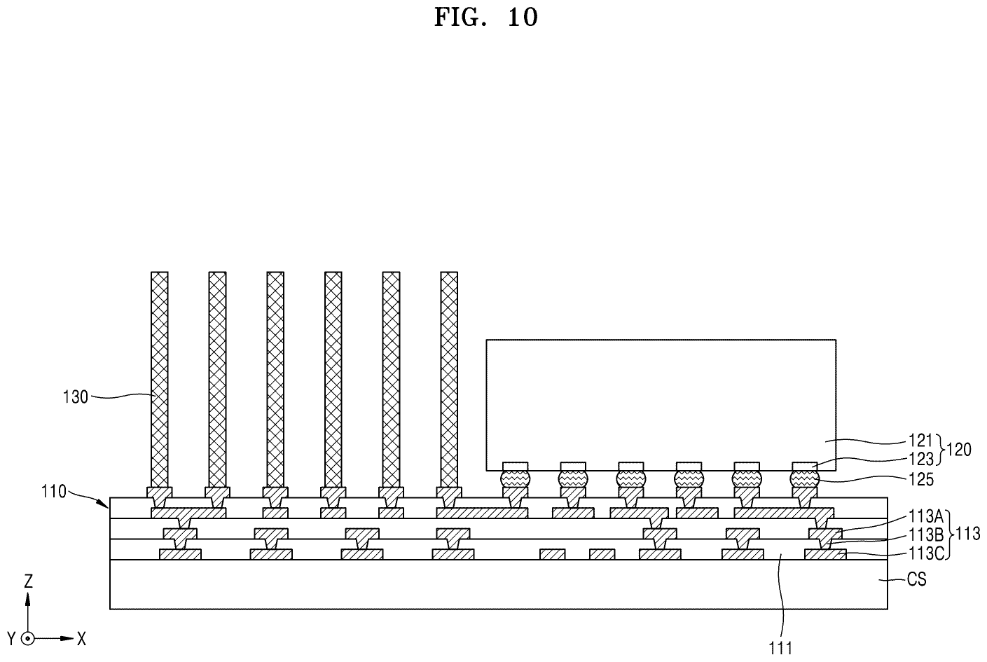

Referring to FIG. 10, the first semiconductor chip 120 may be mounted on the first redistribution structure 110.

The first semiconductor chip 120 may be electrically connected to the first redistribution conductive layer 113 through the first connection bump 125, and may be mounted on the first redistribution structure 110 in parallel to the plurality of conductive posts 130 in the horizontal direction (X direction and/or Y direction).

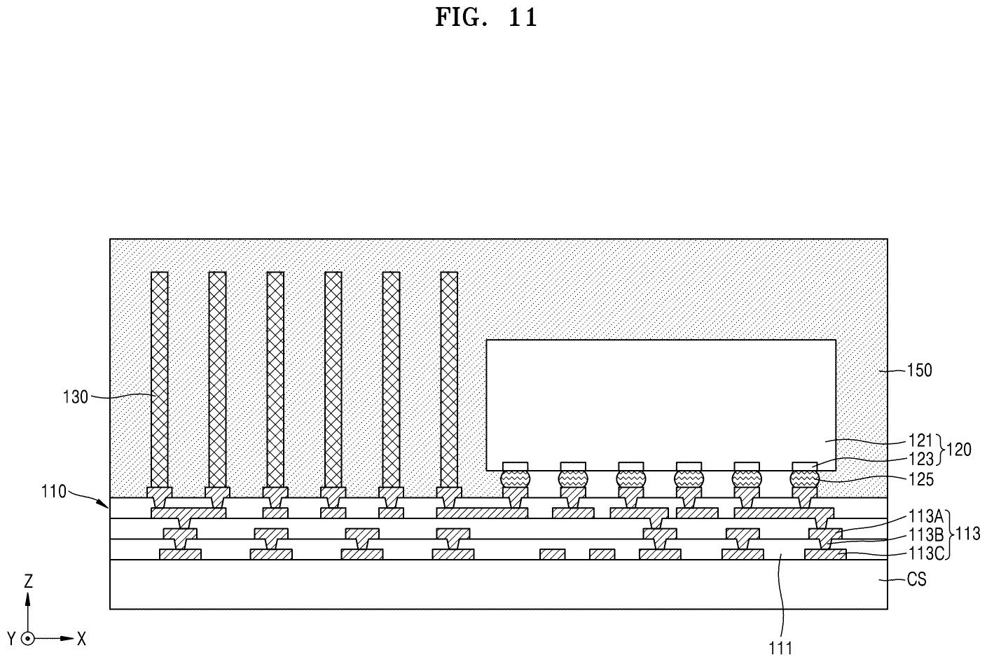

Referring to FIG. 11, the molding member 150 at least partially covering the first semiconductor chip 120 and the plurality of conductive posts 130 may be formed on the first redistribution structure 110.

To form the molding member 150, a molding material such as an epoxy molding compound may be supplied to the carrier substrate CS, and then may be cured.

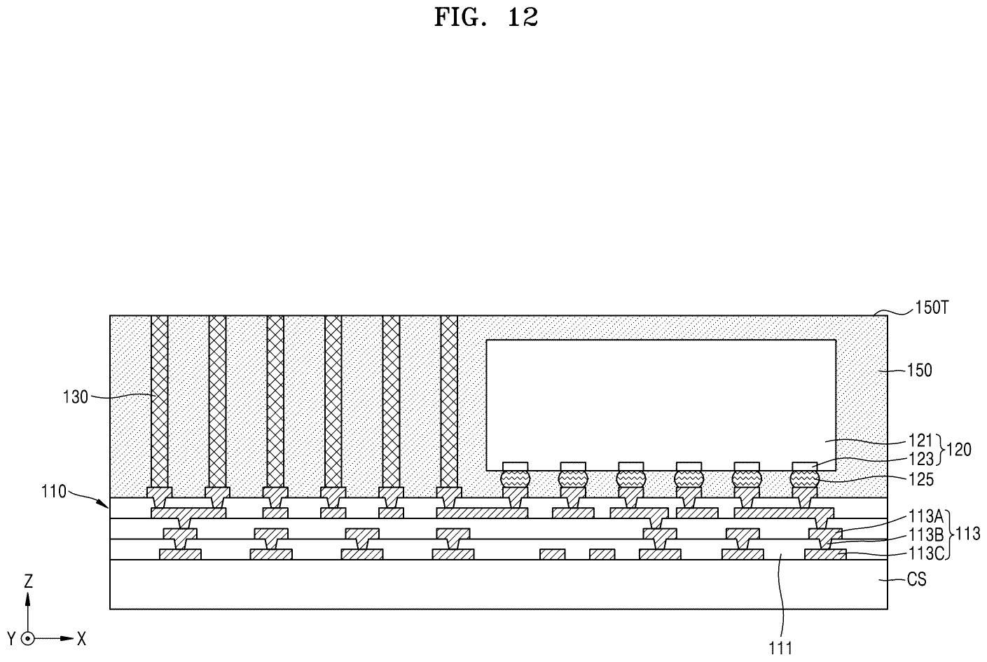

Referring to FIG. 12, an upper portion of the molding member 150 may be removed to expose the plurality of conductive posts 130.

To remove the upper portion of the molding member 150, a chemical mechanical polishing (CMP) process, a grinding process, or the like may be performed. In some embodiments, upper portions of the plurality of conductive posts 130 may also be removed through a polishing process. As a result of the polishing process, the top surface 150T of the molding member 150 may be located on the same plane as top surfaces of the plurality of conductive posts 130.

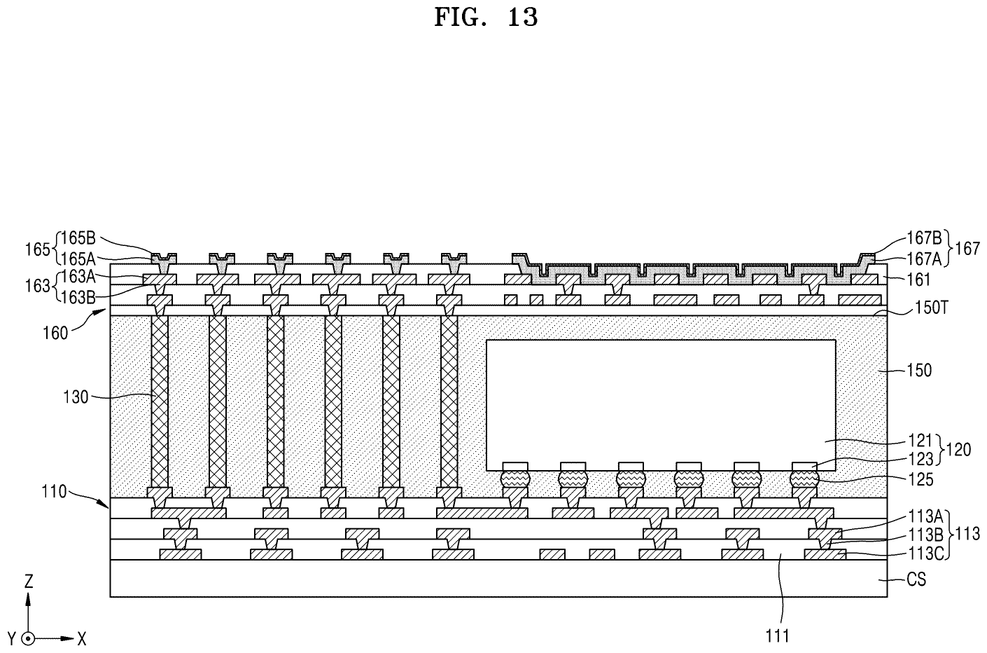

Referring to FIG. 13, the second redistribution structure 160 may be formed on the top surface 150T of the molding member 150 and the top surfaces of the plurality of conductive posts 130.

The second redistribution structure 160 may include the second redistribution insulating layer 161 and the second redistribution conductive layer 163, insulated by the second redistribution insulating layer 161, which are sequentially stacked. The second redistribution conductive layer 163 may include the second conductive pattern 163A extending along a top surface of any one insulating layer of the second redistribution insulating layer 161, and the second via pattern 163B extending by passing through any one insulating layer of the second redistribution insulating layer 161.

The redistribution conductive layer 163 may include the plurality of first marking pads 165 and one second marking pad 167 disposed on the second conductive patterns 163A. The plurality of first marking pads 165 may respectively contact top surfaces of the second conductive patterns 163A. Unlike this, one second marking pad 167 may be conformally formed while contacting a top surface and a side wall or side surface of each of the second conductive patterns 163A to fill a gap between the second conductive patterns 163A.

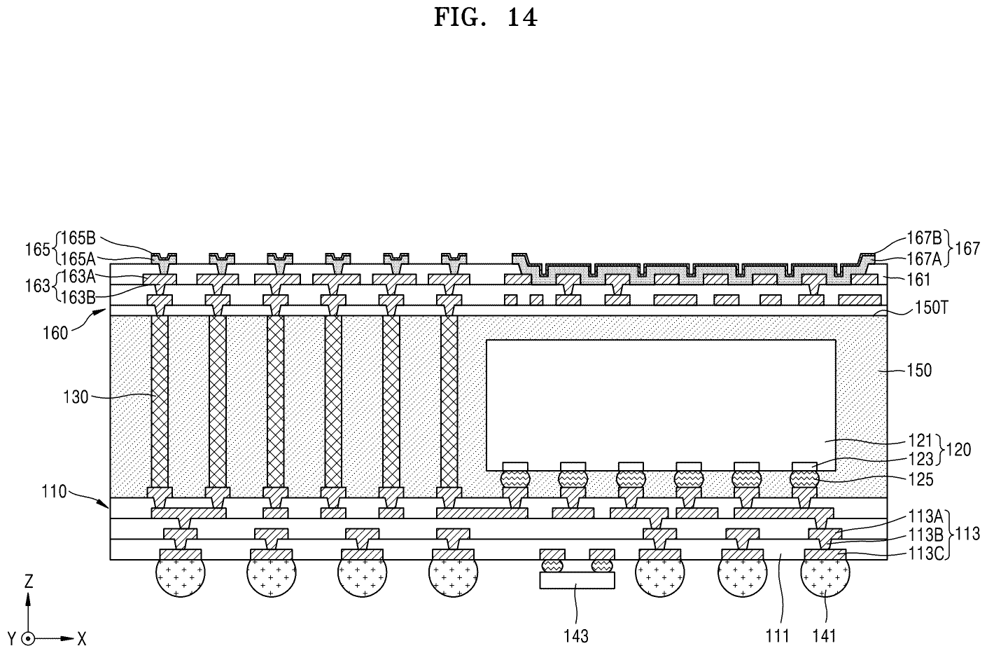

Referring to FIG. 14, the carrier substrate CS (see FIG. 13) may be removed from the first redistribution structure 110.

After the carrier substrate CS is removed, the external connection terminal 141 and the passive component 143 may be attached or connected below the first redistribution structure 110.

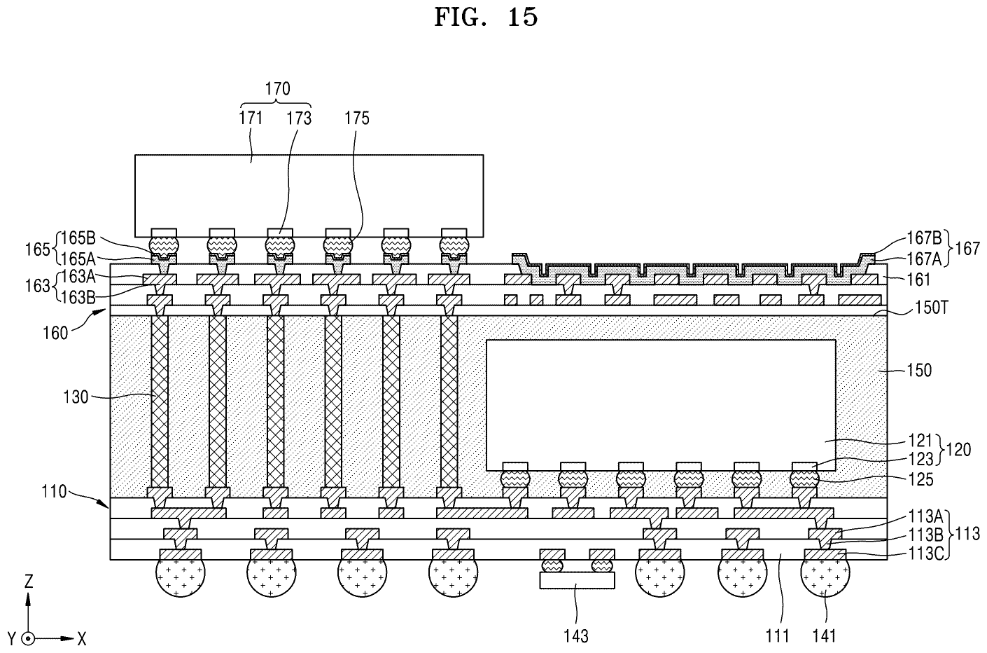

Referring to FIG. 15, the second semiconductor chip 170 may be mounted on the second redistribution structure 160.

In some embodiments, the second semiconductor chip 170 may be mounted on the second redistribution structure 160 so as not to overlap the first semiconductor chip 120 in the vertical direction (Z direction).

The second semiconductor chip 170 may include the second semiconductor substrate 171 and the second connection pad 173. A process of mounting the second semiconductor chip 170 may include seating the plurality of second connection bumps 175, disposed under the second semiconductor chip 170, on the plurality of first marking pads 165 and electrically and physically connecting the second semiconductor chip 170 to the second redistribution conductive layer 163.

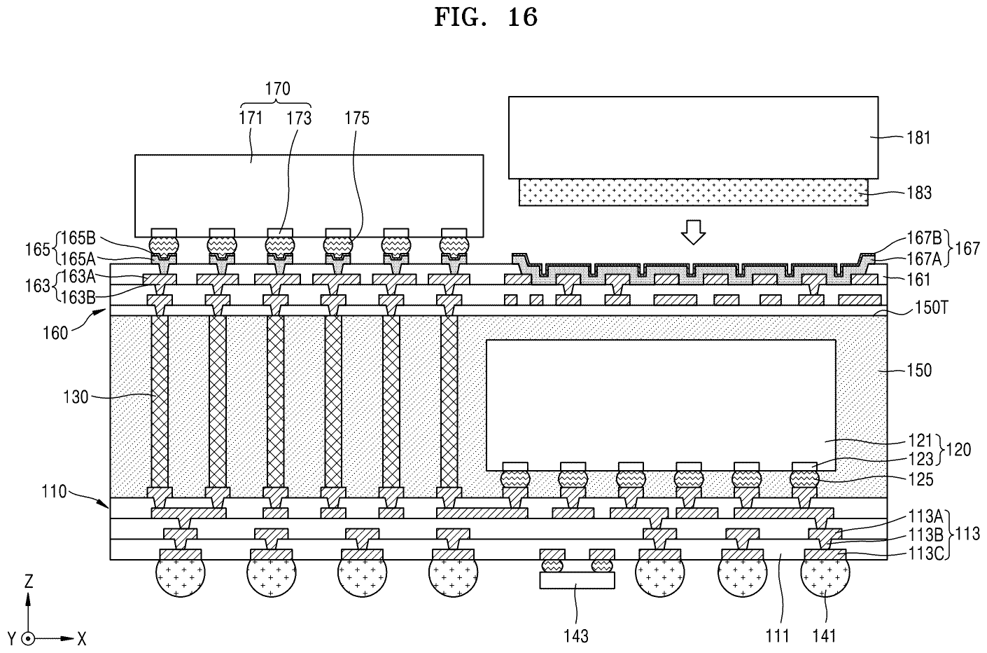

Referring to FIG. 16, the heat dissipation structure 181 may be attached or connected to the second redistribution structure 160.

In some embodiments, the heat dissipation structure 181 may be attached to the second redistribution structure 160 to at least partially overlap the first semiconductor chip 120 in the vertical direction (Z direction).

The heat dissipation structure 181 may be attached or connected to the second redistribution structure 160 through the thermal interface material 183. A process of attaching the heat dissipation structure 181 may include seating the thermal interface material 183, disposed under the heat dissipation structure 181, on one second marking pad 167 and thermally and physically connecting the heat dissipation structure 181 to the second redistribution conductive layer 163.

The semiconductor package 10 described with reference to FIGS. 1 and 2 may be manufactured through the above manufacturing method.

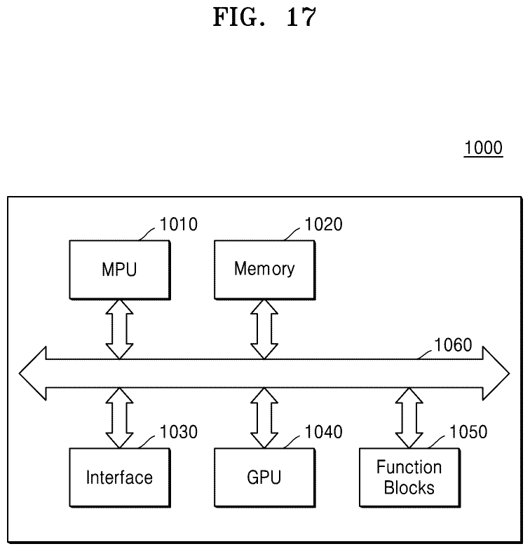

FIG. 17 is a diagram schematically illustrating a configuration of a semiconductor package, according to some embodiments.

Referring to FIG. 17, a semiconductor package 1000 may include a microprocessing unit (MPU) 1010, a memory 1020, an interface 1030, a graphics processing unit (GPU) 1040, function blocks 1050, and a bus 1060 connecting them.

The semiconductor package 1000 may include both the microprocessing unit 1010 and the graphics processing unit 1040 or may include only one of the microprocessing unit 1010 and the graphics processing unit 1040.

The microprocessing unit 1010 may include a core and a cache. For example, the microprocessing unit 1010 may include multi-cores. The multi-cores may have different functions or the same function. Also, the multi-cores may be activated simultaneously or at different times.

The memory 1020 may store results processed by the function blocks 1050 under the control of the microprocessing unit 1010. The interface 1030 may transmit and receive information or signals to and from external devices. The graphics processing unit 1040 may perform graphic functions. For example, the graphics processing unit 1040 may perform a video codec or may process 3D graphics. The function blocks 1050 may perform various functions. For example, when the semiconductor package 1000 is an application processor used in a mobile device, some of the function blocks 1050 may perform a communication function.

The semiconductor package 1000 may include any one of the semiconductor packages 10, 20, 30, 40, 50, and 60 described above.

While example embodiments have been particularly shown and described with reference to the attached drawings, it will be understood by one of ordinary skill in the art that various changes in form and details may be made therein without departing from the spirit and scope of the inventive concept. Accordingly, the above embodiments are examples only in all aspects and are not limited.

While the inventive concept has been particularly shown and described with reference to example embodiments thereof, it will be understood that various changes in form and details may be made therein without departing from the spirit and scope of the following claims.

What is claimed is:

1. A semiconductor package comprising:
a first redistribution structure comprising a first redistribution insulating layer and a first redistribution conductive layer;
a first semiconductor chip on the first redistribution structure;
a molding member on the first redistribution structure and at least partially surrounding the first semiconductor chip;
a second redistribution structure on the molding member, and comprising a second redistribution insulating layer and a second redistribution conductive layer;
a conductive post extending through the molding member to electrically connect the first redistribution conductive layer and the second redistribution conductive layer to each other;
a second semiconductor chip on the second redistribution structure;
a heat dissipation structure spaced apart from the second semiconductor chip in a horizontal direction and overlapping at least a portion of the first semiconductor chip in a vertical direction; and
a thermal interface material between the second redistribution structure and the heat dissipation structure,
wherein a top surface of the thermal interface material is a flat surface and a bottom surface of the thermal interface material is an uneven surface.

2. The semiconductor package of claim 1, wherein the second redistribution conductive layer comprises:
a plurality of first marking pads on which a plurality of solder bumps disposed under the second semiconductor chip are seated; and
a second marking pad on which the thermal interface material is seated,
wherein the plurality of first marking pads are electrically separated from each other by the second redistribution insulating layer, and
the second marking pad is integrally formed as one body.

3. The semiconductor package of claim 2, wherein the second redistribution conductive layer comprises redistribution conductive patterns under the plurality of first marking pads and the second marking pad,
wherein the second marking pad fills a gap between the redistribution conductive patterns.

4. The semiconductor package of claim 3, wherein
a vertical level of an uppermost surface of the plurality of first marking pads is substantially the same as a vertical level of an uppermost surface of the second marking pad, and
a vertical level of a lowermost surface of the plurality of first marking pads is higher than a vertical level of a lowermost surface of the second marking pad.

5. The semiconductor package of claim 4, wherein the second marking pad includes a two-stage uneven structure comprising a first recess portion and a plurality of second recess portions disposed inside the first recess portion,
wherein the uneven surface of the thermal interface material is engaged with the two-stage uneven structure of the second marking pad.

6. The semiconductor package of claim 5, wherein the thermal interface material fills the two-stage uneven structure of the second marking pad and exposes both of opposite side walls of the second marking pad.

7. The semiconductor package of claim 6, wherein the thermal interface material is in contact with the second redistribution conductive layer, but is not in contact with the second redistribution insulating layer.

8. The semiconductor package of claim 5, wherein the thermal interface material fills the two-stage uneven structure of the second marking pad and surrounds both of opposite side walls of the second marking pad.

9. The semiconductor package of claim 8, wherein the thermal interface material is in contact with the second redistribution conductive layer and the second redistribution insulating layer.

10. The semiconductor package of claim 1, wherein a width of the heat dissipation structure in the horizontal direction is greater than a width of the thermal interface material in the horizontal direction.

11. A semiconductor package comprising:
a first redistribution structure comprising a first redistribution insulating layer and a first redistribution conductive layer;
a first semiconductor chip on the first redistribution structure;
a molding member on the first redistribution structure and at least partially surrounding the first semiconductor chip;
a second redistribution structure on the molding member and comprising a second redistribution insulating layer and a second redistribution conductive layer;
a plurality of conductive posts extending through the molding member to electrically connect the first redistribution conductive layer and the second redistribution conductive layer to each other;
a second semiconductor chip on the second redistribution structure;
a heat dissipation structure spaced apart from the second semiconductor chip in a horizontal direction and overlapping at least a major portion of the first semiconductor chip in a vertical direction; and
a thermal interface material between the second redistribution structure and the heat dissipation structure,
wherein the second redistribution conductive layer comprises lower conductive patterns and an upper marking pad on the lower conductive patterns,
wherein the upper marking pad comprises: a plurality of first marking pads on which a plurality of solder bumps disposed under the second semiconductor chip are seated; and a plurality of second marking pads on which the thermal interface material is seated,
wherein the plurality of second marking pads conformally contact the lower conductive patterns while filling a gap between the lower conductive patterns.

12. The semiconductor package of claim 11, wherein each of the plurality of second marking pads has an uneven structure,
wherein the thermal interface material fills the uneven structure of each of the plurality of second marking pads.

13. The semiconductor package of claim 12, wherein the thermal interface material has a top surface and a bottom surface, the top surface contacting the heat dissipation structure, and the bottom surface contacting the plurality of second marking pads,
wherein the top surface of the thermal interface material is a flat surface and the bottom surface of the thermal interface material is an uneven surface.

14. The semiconductor package of claim 12, wherein
the second semiconductor chip is electrically connected to the plurality of conductive posts through the plurality of first marking pads, and
the heat dissipation structure is configured to discharge heat generated from the first semiconductor chip, through the plurality of second marking pads.

15. The semiconductor package of claim 14, wherein the first semiconductor chip comprises a logic device, and the second semiconductor chip comprises a memory device.

16. A semiconductor package comprising:
a first redistribution structure comprising a first redistribution insulating layer and a first redistribution conductive layer;
a first semiconductor chip on the first redistribution structure;
a plurality of first connection bumps between the first semiconductor chip and the first redistribution structure;
a molding member on the first redistribution structure and covering a top surface and a side surface of the first semiconductor chip;
a second redistribution structure on the molding member, and comprising a second redistribution insulating layer and a second redistribution conductive layer;
a plurality of conductive posts extending through the molding member to electrically connect the first redistribution conductive layer and the second redistribution conductive layer to each other;
a second semiconductor chip on the second redistribution structure;
a plurality of second connection bumps between the second semiconductor chip and the second redistribution structure;
a heat dissipation structure spaced apart from the second semiconductor chip in a horizontal direction and overlapping at least a portion of the first semiconductor chip in a vertical direction; and
a thermal interface material between the second redistribution structure and the heat dissipation structure,
wherein the second redistribution conductive layer comprises:
a plurality of first marking pads on which the plurality of second connection bumps are seated;
a second marking pad on which the thermal interface material is seated; and
a plurality of conductive patterns under the plurality of first marking pads and the second marking pad,
wherein the second marking pad is integrally formed as a single body having an uneven structure,
wherein the thermal interface material fills the uneven structure of the second marking pad.

17. The semiconductor package of claim 16, wherein the second marking pad has a two-stage uneven structure comprising a first recess portion and a plurality of second recess portions disposed inside the first recess portion,
wherein the thermal interface material has a top surface and a bottom surface, the top surface contacting the heat dissipation structure, and the bottom surface mated with the two-stage uneven structure of the second marking pad.

18. The semiconductor package of claim 17, wherein the bottom surface of the thermal interface material is in contact with the second redistribution conductive layer, but is not in contact with the second redistribution insulating layer.

19. The semiconductor package of claim 16, wherein
a width of the thermal interface material in the horizontal direction is less than a width of the heat dissipation structure in the horizontal direction,
a planar area of the thermal interface material is about 70% to about 90% of a planar area of the heat dissipation structure, and
a thickness of the thermal interface material is about 45 μm to about 55 μm.

20. The semiconductor package of claim 16, wherein
a width of each of the plurality of conductive patterns in the horizontal direction is about 10 μm to about 30 μm, and
a separation distance between adjacent conductive patterns among the plurality of conductive patterns is about 10μm to about 30μm,
wherein the separation distance between the plurality of conductive patterns is equal to or greater than the width of each of the plurality of conductive patterns in the horizontal direction.
